(19) United States
(12) Patent Application Publication
(10) Pub. No.: US 2007/0264601 A1
(43) Pub. Date: Nov. 15, 2007

(54) Photosensitive Resin Composition and Photosensitive Dry Film by the Use Thereof

(75) Inventors: Teruhiro Uematsu, Kanagawa (JP); Naoya Katsumata, Kawasaki-shi (JP)

Correspondence Address: THELEN REID BROWN RAYSMAN & STEINER LLP, P. O. BOX 640640, SAN JOSE, CA, 95164-0640, US

(73) Assignee: Tokyo Ohka Kogyo Co., Ltd, Kanagawa (JP)

(21) Appl. No.: 11/667,051

(22) PCT Filed: Oct. 19, 2005
(86) PCT No.: PCT/JP05/19652

§ 371 Date: May 3, 2007

(30) Foreign Application Priority Data
Nov. 4, 2004 (JP) 2004-320515

(51) Int. Cl. G03F 7/033; G03F 7/031; G03F 7/032

(52) U.S. Cl. 430/496

(57) ABSTRACT

A photosensitive resin composition for h-ray exposure which has high sensitivity for h-ray and is excellent in resolution of a resist pattern, and a photosensitive dry film by the use thereof are provided. The photosensitive resin composition is composed of an alkali-soluble resin (A) having an alicyclic epoxy group-containing unsaturated compound in a part of a carboxyl group of a carboxyl group-containing acryl copolymer as well as having a weight-average molecular weight of 1,000 to 100,000, an ethylenically unsaturated compound (B) and a photopolymerization initiator (C) including at least a photopolymerization initiator (C1) whose absorption coefficient for light with a wavelength of 405 nm is 1 or more as an essential component.

### TECHNICAL FIELD

The present invention relates to a photosensitive resin composition and a photosensitive dry film by the use thereof, in particular relates to a photosensitive resin composition which is excellent in development property and can give a resist pattern excellent in resolution when made into a dry film, and in particular relates to a photopolymerizable composition suitable for directly forming an image by laser light with a wavelength of 390 to 430 nm.

### BACKGROUND ART

As is well-known, dry films are used for forming resists for wiring circuit formation in the production of print wiring boards. This dry film is made by at least forming a photosensitive resin layer in a semidried state on a support film.

The above photosensitive resin composition contains a polymer (resin) component (A), a photopolymerizable monomer component (B) and a photopolymerization initiator (C) as essential components. As the photosensitive resin composition for a dry film, for example, a constitution using a functional polymer having an unsaturated group number of 0.3 to 3.5 mmol/g obtained by reacting a carboxyl group-containing polymer having no unsaturated group and an alicyclic epoxy group-containing unsaturated compound with a carboxyl group-containing polymer as the polymer (resin) component (A), using an ethylenically unsaturated compound as the monomer component (B), and using a commonly used photopolymerization initiator as the photopolymerization initiator (C) has been disclosed (e.g., Patent Document 1 and the like).

As exposure light for giving pattern exposure to a resist film formed from the photosensitive resin composition, ultraviolet light has been conventionally used. The ultraviolet light used includes g-ray, h-ray and i-ray whose main wavelengths are 436 nm, 405 nm and 365 nm, respectively. The pattern to be formed is finer, the exposure light with shorter wavelength is required.

Recently, finer wiring circuits have been desired, and patterning using the i-ray has been increased. Along with that, resin compositions having high photosensitivity for the i-ray have been provided. The photosensitive resin compositions currently provided including the above Patent Document 1 are excellent particularly in sensitivity for the i-ray. The g-ray by which relatively high illumination intensity was obtained was a mainstream in 1980s, but as described above, the shorter the wavelength of the exposure light is, the finer the pattern can be formed. Therefore, the i-ray has been used as the exposure light at a burst in 1990s and from that time onwards. Thus, numerous photosensitive resin compositions whose photosensitive property is suitable for the g-ray have been developed, and the photosensitive resin compositions having the photosensitive property suitable for the i-ray haven been frequently developed recently as is shown in the above Patent Document 1.

However, a mercury lamp used for i-ray exposure is an extremely inefficient light source because most energy given to drive is changed to heat. From such a reason in conjunction with recent advance of wavelength shortening of semiconductor laser, h-ray laser exposure with good energy efficiency has been gotten a lot of attention, and some methods and apparatuses for the h-ray exposure have been proposed (e.g., Patent Document 2, etc.).

However, as described above, since technical transition from the g-ray exposure to the i-ray exposure has progressed at a burst, investigation of the photosensitive resin compositions having the optimal property for the h-ray exposure remains insufficient. Therefore, in the present circumstances, the photosensitive resin compositions for the i-ray exposure disclosed in the aforementioned Patent Document 1 is diverted and used as the photosensitive resin composition for the wiring circuit formation using the h-ray as the exposure light.

Patent Document 1: Japanese Patent Application Laid-Open No.2003-76014 A

Patent Document 2: Japanese Patent Application Laid-Open No. 2004-191938 A

However, in the present circumstances, no sufficiently satisfied photosensitive resin composition optimized for the h-ray exposure is easily found. In particular, it has been pointed out that the resolution is insufficient. For example, an aspect ratio of the formed pattern is currently about 2, but the aspect ratio equivalent to or more than that is desired.

### DISCLOSURE OF THE INVENTION

The present invention has been made in the light of the above circumstances, and an object of the invention is to provide a photosensitive resin composition which has high sensitivity for h-ray and is excellent in resolution of a resist pattern, and a photosensitive dry film by the use thereof.

As a result of an extensive study for solving the above problems, the present inventors have found that sensitivity and resolution of a resist pattern may be dramatically enhanced when h-ray (main wavelength: 405 nm) is used as exposure light by using a photosensitive resin composition comprising at least an alkali-soluble resin (A), an ethylenically unsaturated compound (B) and a photopolymerization initiator (C), wherein the alkali-soluble resin with a weight-average molecular weight of 1,000 to 100,000 having an alicyclic epoxy group-containing unsaturated compound in a part of a carboxyl group of a carboxyl group-containing acryl copolymer is used as the above alkali-soluble resin (A). They have further found that it may be assured to enhance the sensitivity and the resolution of the resist pattern by the use of the above alkali-soluble resin (A), by using as the above photopolymerization initiator (C) the photopolymerization initiator having a photopolymerization initiator (C1) having a high absorption property for at least light with a wavelength of 405 nm as an essential component in addition to the use of the alkali-soluble resin (A). The resolution of the resist pattern is remarkably enhanced by such a constitution, and for example, when the resist with a thickness of 30 μm is formed, an aspect ratio of the resist pattern formed by exposure with h-ray laser is 2.7 or more.

The present invention has been made based on the above findings. That is, the photosensitive resin composition according to the invention comprises at least the alkali-soluble resin (A), the ethylenically unsaturated compound(B) and the photopolymerization initiator (C), and is characterized in that the above alkali-soluble resin (A) has the alicyclic epoxy group-containing unsaturated compound in the part of the carboxyl group of the carboxyl group-containing acryl copolymer and has the weight-average molecular weight of 1,000 to 100,000, and in that the above photopolymerization initiator (C) comprises at least the photopolymerization initiator (C1) whose absorption coefficient is 1 or more for the light at a wavelength of 405 nm as the essential component.

The photosensitive dry film of the present invention is also characterized by having at least a photosensitive resin layer formed from the above photosensitive resin composition on a support film.

By the use of the photosensitive resin composition of the present invention, the photosensitive resin layer which is excellent in sensitivity for the h-ray and resolution of the resist pattern may be formed. The photosensitive resin layer formed using the photosensitive resin composition of the invention is drastically excellent in sensitivity for the h-ray and resolution of the resist pattern.

The photosensitive dry film of the present invention has the high sensitivity for the h-ray, is excellent in resolution of the resist pattern and is also excellent in adhesion.

### BEST MODE(S) FOR CARRYING OUT THE INVENTION

Embodiments of the present invention will be described below.

As described above, the photosensitive resin composition of the invention comprises at least the alkali-soluble resin (A), the ethylenically unsaturated compound (B) and the photopolymerization initiator (C), and is characterized in that the above alkali-soluble resin (A) has the alicyclic epoxy group-containing unsaturated compound in the part of the carboxyl group of the carboxyl group-containing acryl copolymer as well as the weight-average molecular weight of 1,000 to 100,000, and in that the above photopolymerization initiator (C) comprises at least the photopolymerization initiator (C1) whose absorption coefficient is 1 or more for the light at wavelength of 405 nm as the essential component.

Alkali-Soluble Resin (A)

The alkali-soluble resin (A) used for the photosensitive resin composition of the present invention has the alicyclic epoxy group-containing unsaturated compound in the part of the carboxyl group of the carboxyl group-containing acryl copolymer as well as the weight-average molecular weight of 1,000 to 100,000. This carboxyl group-containing acryl copolymer is a reaction product of an acid group-containing acrylic resin (a1) obtained by polymerizing an ethylenically unsaturated acid as the essential component with an alicyclic epoxy-group-containing unsaturated compound (a2) containing no ester bond formed by a ring opening addition reaction between an epoxy group and a carboxy group.

As the above acid group-containing acrylic resin (a1), a publicly known copolymer obtained by copolymerizing one or more polymerizable monomers selected from esters of (meth)acrylic acid, vinyl aromatic compounds, amide based unsaturated compounds, hydroxyl group-containing acrylate or phthalate, polyolefin based compounds, (meth)acrylonitrile, methyl isopropenyl ketone, vinyl acetate, vinyl butyrate, vinyl propionate, methacrylonitrile, isoprene, chloroprene, 3-butadiene and vinyl pivalate with its essential component which is (meth)acrylic acid, 2-carboxyethyl(meth)acrylate, 2-carboxypropyl(meth)acrylate, crotonic acid, maleic acid, fumaric acid, itaconic acid, cinnamic acid, sorbic acid, propolic acid, and ethylenically unsaturated acid such as half ester or anhydride thereof is used.

Examples of the aforementioned esters of (meth)acrylic acids may include methyl(meth)acrylate, ethyl(meth)acrylate, n-propyl(meth)acrylate, i-propyl(meth)acrylate, n-butyl(meth)acrylate, i-butyl(meth)acrylate, sec-butyl(meth)acrylate, tert-butyl(meth)acrylate, 3-ethylhexyl(meth)acrylate, isooctyl(meth)acrylate, decyl(meth)acrylate, isodecyl(meth)acrylate, lauryl(meth)acrylate, tridecyl(meth)acrylate, isomyristyl(meth)acrylate, hexadecyl(meth)acrylate, and stearyl(meth)acrylate.

The aforementioned vinyl aromatic compounds may include α-methylstyrene, o-vinyltoluene, m-vinyltoluene, p-vinyltoluene, o-chlorostyrene, m-chlorostyrene, p-chlorostyrene, o-methoxystyrene, m-methoxystyrene and p-methoxystyrene.

Examples of the aforementioned amide based unsaturated compounds may include acrylamide and methacrylamide.

Examples of the aforementioned hydroxyl group-containing acrylate or phthalate may include 2-hydroxy-3-phenoxypropyl(meth)acrylate, 2-acryloyoxyethyl-2-hydroxyethyl phthalate, 2-methacryloyoxyethyl-2-hydroxypropyl phthalate, 2-hydroxyethyl(meth)acrylate, 2-hydroxybutyl(meth)acrylate, 3-hydroxybutyl(meth)acrylate, 4-hydroxybutyl(meth)acrylate, ethylene glycol mono(meth)acrylate, glycerol(meth)acrylate, dipentaerythritol mono(meth)acrylate, tetrahydrofurfuryl(meth)acrylate, o-hydroxystyrene, m-hydroxystyrene and p-hydroxystyrene.

The aforementioned alicyclic epoxy group-containing unsaturated compound (a2) is a compound having one radical polymerizable unsaturated group and an alicyclic epoxy group in a molecule, and is preferably, for example, 3,4-epoxycyclohexylmethyl acrylate.

The aforementioned alkali-soluble resin (A) is produced by reacting a part of the acid group derived from the above acid group-containing acrylic resin (a1) with the epoxy group derived from the above alicyclic epoxy group-containing unsaturated compound (a2) to introduce the unsaturated group into the above acid group-containing acrylic resin (a1). Since this unsaturated group is required for curing by the exposure light, an acid value of this resin (a1) is 15 or more, and preferably in the range of 40 to 500.

The weight-average molecular weight of the aforementioned alkali-soluble resin (A) is preferably 1,000 to 100,000, more preferably 3,000 to 70,000, and still more preferably 9,000 to 30,000. As described above, this alkali-soluble resin (A) is curable by light and heat because of having a double bond in a side chain, and soluble in an alkali solution because of having carboxylic acid in a side chain. That is, this alkali-soluble resin (A) itself has high photosensitivity and alkali-solubility. A crosslinking rate one another of the resin itself may be increased by adjusting the molecular weight in the relatively small range even within the range of the weight-average molecular weight of 1,000 to 100,000 because the resin itself has the high photosensitivity. That is, a cured level by the exposure may be increased. In the present invention, by the use of the alkali-soluble resin (A) having the above properties, a development property after the exposure becomes good, a contrast between a cured area and an uncured area is enhanced, and consequently the resolution of the resist pattern may also be enhanced. The weight-average molecular weight may be measured by a gel permeation chromatography method.

In the photosensitive resin composition of the present invention, a favorable effect may be obtained even without particularly adding a binder resin in addition to the above alkali-soluble resin (A), but the binder resin may be added as long as the addition thereof does not disturb the effect of the invention. But, when the binder resin in addition to the above alkali-soluble resin (A) is added to the photosensitive resin composition of the invention, it is preferable that the binder resin in addition to the above alkali-soluble resin (A) is added at a concentration of 20% or less and preferably 10% or less based on a whole resin amount. Because the resolution becomes poor when the concentration of the binder resin in addition to the above alkali-soluble resin (A) exceeds 20%.

Examples of the binder resin in addition to the above alkali-soluble resin (A) may include (meth)acryl based resins, styrene based resins, epoxy based resins, amide based resins, amide epoxy based resins, aikido based resins, phenol based resins, phenol novolak based resins and cresol novolak based resins. The (meth)acryl based resin is preferable in terms of alkali development property.

A glass transition temperature (Tg) of the above alkali-soluble resin (A) is preferably 100° C. or more, and more preferably in the range of 100° C. to 150° C. By adjusting the glass transition temperature (Tg) of the above alkali-soluble resin (A) in this range, the effects that resist curability is increased and dimension accuracy of the resist pattern is enhanced may be obtained.

Ethylenically Unsaturated Compound (B)

The ethylenically unsaturated compound (B) used in the present invention plays a role to prevent adhesion to a substrate from becoming inferior at the same time when cured hardness is increased to enhance the dimension accuracy by setting the high glass transition temperature (Tg) of the above alkali-soluble resin (A). Thus, it is preferable that this ethylenically unsaturated compound (B) contains a monomer (B1) which is excellent in flexibility. As this monomer (B1), a straight monomer with a molecular weight of 500 to 2,000 is appropriate. As such a straight monomer with a molecular weight of 500 to 2,000, specifically, at least one selected from the group consisting of polyalkylene glycol di(meth)acrylate and 2,2-bis[4-((meth)acryloxy polyethoxy)phenyl]propane whose molecular weights are in the range of 500 to 2,000 may be used. The molecular weight may be theoretically calculated from a molecular formula.

Examples of the above polyalkylene glycol di(meth)acrylate may include polyethylene glycol di(meth)acrylate, polypropylene glycol di(meth)acrylate, and polyethylene polypropylene glycol di(meth)acrylate.

Examples of the above 2,2-bis[4-((meth)acryloxy polyethoxy)phenyl]propane may include 2,2-bis[4-((meth)acryloxy pentaethoxy)phenyl]propane and 2,2-bis[4-((meth)acryloxy decathoxy)phenyl]propane. 2,2-Bis[4-((meth)acryloxy pentaethoxy)phenyl]propane and 2,2-bis[4-((meth)acryloxy decathoxy)phenyl]propane are commercially available and suitably used as “BPE-500” (Shin-Nakamura Chemical Co., Ltd.) and “BPE1300” (Shin-Nakamura Chemical Co., Ltd.), respectively.

In the present invention, it is possible to further use another photopolymerizable monomer (B2) in order to help the effect of the above monomer (B1). As such a photopolymerizable monomer (B2), trimethylolpropane triacrylate and polyethylene glycol dimethacrylate are suitable, and additionally it is possible to use the following compounds.

As a photopolymerizable monomer (B2) component, for example, polyhydric alcohol, compounds obtained by reacting α,β-unsaturated carboxylic acid with polyhydric alcohol, compounds obtained by reacting α,β-unsaturated carboxylic acid with 2,2-bis[4-((meth)acryloxy polyethoxy)phenyl]propane and glycidyl group-containing compounds, urethane monomers, nonylphenyloxylene(meth)acrylate, γ-chloro-β-hydroxypropyl-β′-(meth)acryloyloxyethyl-o-phthalate, β-hydroxyethyl-β′-(meth)acryloyloxyethyl-o-phthalate, β-hydroxypropyl-β′-(meth)acryloyloxyethyl-o-phthalate, and (meth)acrylic acid alkyl ester may be further used.

Examples of the aforementioned compounds obtained by reacting α,β-unsaturated carboxylic acid with polyhydric alcohol may include ethylene glycol di(meth)acrylate, polyethylene glycol di(meth)acrylate, propylene glycol di(meth)acrylate, polypropylene glycol di(meth)acrylate, polyethylene polypropylene glycol di(meth)acrylate, trimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylol propane pentaethoxy tri(meth) acrylate, tetramethylolmethane tri(meth)acrylate, tetramethylolmethane tetra(meth)acrylate, tetramethylolpropane tetra(meth)acrylate, pentaerythritol tri(meth)acrylate, pentaerythritol tetra(meth)acrylate, pentaerythritol penta(meth)acrylate, dipentaerythritol penta(meth)acrylate, and dipentaerythritol hexa(meth)acrylate.

Examples of the aforementioned α,β-unsaturated carboxylic acid may include (meth)acrylic acid.

Examples of the above compounds obtained by reacting α,β-unsaturated carboxylic acid with 2,2-bis[4-((meth)acryloxy polyethoxy)phenyl]propane may include 2,2-bis[4-((meth)acryloxy diethoxy)phenyl]propane and 2,2-bis[4-((meth)acryloxy triethoxy)phenyl]propane.

Examples of the above compounds obtained by reacting α,β-unsaturated carboxylic acid with the glycidyl group-containing compound may include trimethylolpropane triglycidyl ether tri(meth)acrylate and 2,2-bis(4-(meth)acryloxy-2-hydroxy-propyloxy)phenyl.

Examples of the aforementioned urethane monomer may include addition reactants of (meth)acryl monomer having an OH group at position β with isophorone diisocyanate, 2,6-toluene diisocyanate, 2,4-toluene diisocyanate or 1,6-hexamethylene diisocyanate, tris[(meth)acryloxy tetraethylene glycol isocyanate]hexamethylene isocyanurate, EO-modified urethane di(meth)acrylate, and EO- and PO-modified urethane di(meth)acrylate.

Examples of the above (meth)acrylic acid alkyl ester may include (meth)acrylic acid methyl ester, (meth)acrylic acid ethyl ester, (meth)acrylic acid butyl ester and (meth)acrylic acid 2-ethylhexyl ester.

Photopolymerization Initiator (C)

The photopolymerization initiator (C) used in the present invention is characterized by comprising at least a photopolymerization initiator (C1) whose absorption coefficient for the light with a wavelength of 405 nm is 1 or more as the essential component. When the absorption coefficient is less than 1, the absorption of the h-ray (main wavelength: 405 nm) is low and it is likely that the photosensitive resin layer is not cured.

The absorption coefficient herein may be measured using a method typically used for measuring the absorption coefficient of powder. Specifically, a diluted solution is prepared by diluting the powder whose absorption coefficient is to be measured with PGME (propylene glycol monomethyl ether), and an absorbance is measured using an ultraviolet spectrophotometer (trade name: UV-3100PC supplied from Shimadzu Corporation). Then the absorption coefficient may be calculated using a calculation formula of (Absorbance×Dilution solution (g))/(Powder (g)×1000). At that time, when the absorption coefficient exceeds 2, the diluted solution is adjusted twice by precisely weighing the diluted solution and further diluting with PGME, and the absorption coefficient may be calculated using another calculation formula of (Absorbance×Diluted solution (g)×Diluted solution twice (g)/Powder (g)×Precisely weighed diluted solution (g)×1000).

The photopolymerization initiator (C1) used in the present invention is not particularly limited as long as its absorption coefficient is 1 or more. Specific examples may include 4,4′-bis(diethylamino)benzophenone and 2,4-diethylthioxanthone. Among others, 4,4′-bis(diethylamino)benzophenone is preferable.

The above photopolymerization initiator (C) may comprise at least one other photopolymerization initiator (C2) whose absorption property for the light with a wavelength of 405 nm is lower than that of the above photopolymerization initiator (C1). The absorption coefficient may be adjusted appropriately depending on an intended use of the photosensitive resin composition by comprising the photopolymerization initiator (C2) whose absorption property for the light with a wavelength of 405 nm is lower than that of the above photopolymerization initiator (C1) in the photopolymerization initiator (C). For example, when the photosensitive resin layer is formed and the exposure light is irradiated, a bottom of the photosensitive resin layer may be sufficiently cured by setting the absorption coefficient in the range of 1 to 20.

The above photopolymerization initiator (C2) may include triazine compounds, hexaarylbiimidazole compounds or mixtures thereof.

Examples of the triazine compound may include 2,4,6-tris(trichloromethyl)-s-triazine, 2-phenyl-4,6-bis(trichloromethyl)-s-triazine, 2-methyl-4,6-bis(trichloromethyl)-s-triazine, 2-n-propyl-4,6-bis(trichloromethyl)-s-triazine, 2-(p-chlorophenyl)-4,6-bis(trichloromethyl)-s-triazine, 2-(p-tolyl)-4,6-bis(trichloromethyl)-s-triazine, 2,4-bis(trichloromethyl)-4′-methoxyphenyl-s-triazine, 2-(4-methoxy-naphtho-1-yl)-4,6-bis(trichloromethyl)-s-triazine, 2-(4-ethoxy-naphtho-1-yl)-4,6-bis(trichloromethyl)-s-triazine, 2-[4-(2-ethoxyethyl)-naphtho-1-yl]-4,6-bis(trichloromethyl)-s-triazine, 2-(4,7-dimethoxy-naphtho-1-yl)-4,6-bis(trichloromethyl)-s-triazine, 2-(acenaphtho-5-yl)-4,6-bis(trichloromethyl)-s-triazine, 2-(2′,4′-dichlorophenyl)-4,6-bis(trichloromethyl)-s-triazine, 2-n-nonyl-4,6-bis(trichloromethyl)-s-triazine, 2-(α,α,β-trichloroethyl)-4,6-bis(trichloromethyl)-s-triazine, 2-styryl-4,6-bis(trichloromethyl)-s-triazine, 2-p-methylstyryl-4,6-bis(trichloromethyl)-s-triazine, and 2-p-methoxystyryl-4,6-bis(trichloromethyl)-s-triazine. Among them, 2-methyl-4,6-bis(trichloromethyl)-s-triazine is preferable. Because its curability is favorable even under the low exposure light intensity and the dimension accuracy of the resist pattern is enhanced. The triazine compound may be used alone or in combination of several types.

Examples of the hexaarylbiimidazole compounds usable in the present invention may include 2,2′-bis(o-chlorophenyl)-4,5,4′,5′-tetraphenyl-1,2′-biimidazole, 2,2′-bis(o-chlorophenyl)-4,5,4′,5′-tetraphenyl-1,1′-biimidazole, 2,2′-bis(o-fluorophenyl)-4,5,4′,5′-tetraphenyl-1,1′-biimidazole, 2,2′-bis(o-methoxyphenyl)-4,5,4′,5′-tetraphenyl-1,1′-biimidazole, 2,2′-bis(p-methoxyphenyl)-4,5,4′,5′-tetraphenyl-1,1′-biimidazole, 2,4,2′,4′-bis[bi(p-methoxyphenyl)]-5,5′-diphenyl-1,1′-biimidazole, 2,2′-bis(2,4-dimethoxyphenyl)-4,5,4′,5′-diphenyl-1,1′-biimidazole, 2,2′-bis(p-methylthiophenyl)-4,5,4′,5′-diphenyl-1,1′-biimidazole, bis(2,4,5-triphenyl)-1,1′-biimidazole and 2,2′-bis(2-chlorophenyl)-4,5,4′,5′-tetraphenyl-1,2′-biimidazole. Among them, 2,2′-bis(2-chlorophenyl)-4,5,4′,5′-tetraphenyl-1,2′-biimidazole is preferable. Because, internal curability is enhanced and the dimension accuracy of the resist pattern is enhanced. The hexaarylbiimidazole compound may be used alone or in combination of two or more.

It is more preferable to use the triazine compound and the hexaarylbiimidazole compound as a mixture. A combination ratio is not particularly limited, and is preferably 1 to 20 of the hexaarylbiimidazole compound versus 0.01 to 1 of the triazine compound.

The combination ratio of the above photopolymerization initiator (C1) to the above photopolymerization initiator (C2) varies depending on types of the photopolymerization initiators used. Specifically, when 4,4′-bis(diethylamino)benzophenone is used as the photopolymerization initiator (C1) and 2,2′-bis(2-chlorophenyl)-4,5,4′,5′-tetraphenyl-1,2′-biimidazole is used as the photopolymerization initiator (C2), the ratio of C1/C2 is 0.01 to 5/0.1 to 50, preferably 0.02 to 2/0.5 to 30 and more preferably 0.05 to 1/1 to 20. When the ratio of the photopolymerization initiator (C1) exceeds 5 versus 0.1 to 50 of C2, the absorption of the exposure light (particularly h-ray) is increased, and it is likely that only the surface of the photosensitive resin layer is cured and the bottom is not cured when the photosensitive resin layer is formed and the exposure light is irradiated. Meanwhile, when the ratio of the photopolymerization initiator (C1) is less than 0.01 versus 0.1 to 50 of C2, the absorption of the exposure light is decreased and it is likely that the photosensitive resin layer is not cured.

The photosensitive resin composition of the present invention may further comprise the photopolymerization initiator other than those described above as long as the effects of the invention are not disturbed. Examples of such a photopolymerization initiator may include aromatic ketone such as benzophenone, N,N′-tetramethyl-4,4′-diaminobenzophenone, N,N′-tetraethyl-4,4′-diaminobenzophenone, 4-methoxy-4′-dimethylaminobenzophenone, and 2-benzyl-2-dimethylamino-1-(4-morpholinophenyl)-butanone-1,2-methyl-1-[4-(methylthio)phenyl]-2-morpholino-propanone-1; quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone and 2,3-dimethylanthraquinone; benzoin ether compounds such as benzoin methyl ether, benzoin ethyl ether and benzoin phenyl ether; benzoin compounds such as benzoin, methylbenzoin and ethylbenzoin; benzyl derivatives such as benzyl methyl ketal; 2,4,5-triarylimidazole dimers such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer and 2,4,5-triarylimidazole dimer; acridine derivatives such as 9-phenylacridine and 1,7-bis(9,9′-acridinyl)heptane; N-phenylglycine, and coumarin-based compounds.

Other Components

In the present invention, organic solvents for dilution such as alcohols, ketones, acetic acid esters, glycol ethers, glycol ether esters and petroleum based solvents may be added appropriately for the purpose of adjusting a viscosity if necessary in addition to the above components.

Examples of the above organic solvent for the dilution may include, but are not limited to, hexane, heptane, octane, nonane, decane, benzene, toluene, xylene, benzyl alcohol, methyl ethyl ketone, acetone, methyl isobutyl ketone, cyclohexane, methanol, ethanol, propanol, butanol, hexanol, cyclohexanol, ethylene glycol, diethylene glycol, glycerine, ethylene glycol monomethyl ether, ethylene glycol monoethyl ether, propylene glycol monomethyl ether, propylene glycol monoethyl ether, diethylene glycol monomethyl ether, diethylene glycol monoethyl ether, diethylene glycol dimethyl ether, diethylene glycol diethyl ether, 2-methoxybutyl acetate, 3-methoxybutyl acetate, 4-methoxybutyl acetate, 2-methyl-3-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, methyl lactate, ethyl lactate, methyl acetate, ethyl acetate, propyl acetate, butyl acetate, propylene glycol monomethyl ether acetate, propylene glycol monomethyl ether acetate, propylene glycol monoethyl ether acetate, methyl propionate, ethyl propionate, methyl benzoate, ethyl benzoate, propyl benzoate, butyl benzoate, methyl butyrate, ethyl butyrate, propyl butyrate, and additionally petroleum based solvents available under trade names such as “Swasol” (Maruzen Petrochemical Co., Ltd.) and “Solvets” (Tonen Petrochemical Co., Ltd.).

Other additives such as coloring dyes, adhesion imparting agents, plasticizers, antioxidants, heat polymerization inhibitors, surface tension modifiers, stabilizers, chain transfer agents, anti-foaming agents and flame retardants may also be added appropriately.

The combination ratio of the alkali-soluble resin (A), the ethylenically unsaturated compound (B) and the photopolymerization initiator (C) in the photosensitive resin composition of the present invention is as follows. The amount of the ethylenically unsaturated compound (B) to be combined is 30 to 200 parts by weight, preferably 30 to 150 parts by weight, and more preferably 30 to 100 parts by weight based on 100 parts by weight of the alkali-soluble resin (A). When the amount is less than 30 parts by weight, the adhesion becomes poor because of insufficient cure. Conversely, when the amount is more than 200 parts by weight, the resist component oozes from an edge of the dry film and a peeling property is deteriorated.

The amount of the photopolymerization initiator (C) to be combined is 0.1 to 50 parts by weight, preferably 0.5 to 30 parts by weight, and more preferably 1 to 20 parts by weight based on 100 parts by weight of the alkali-soluble resin (A). When the amount is less than 0.1 parts by weight, the sensitivity is reduced and practicability is poor. Conversely, when the amount is more than 20 parts by weight, the adhesion is reduced.

Photosensitive Dry Film

Subsequently, the photosensitive dry film of the present invention will be described. The photosensitive dry film of the invention is obtained by at least providing the photosensitive resin layer formed from the aforementioned photosensitive resin composition on a support film. When used, the photosensitive resin layer may be provided easily on a material to be processed by lapping the revealing photosensitive resin layer over the material to be processed and subsequently peeling the support film from the photosensitive resin layer.

By the use of the photosensitive dry film of the present invention, the layer having more excellent film thickness uniformity and surface smoothness may be formed compared to the case of forming the photosensitive resin layer by directly applying the photosensitive resin composition onto the material to be processed.

The support film used for producing the photosensitive dry film of the present invention is not particularly limited as long as the photosensitive resin layer formed as a film on the support film can be peeled easily from the support film, which is a mould releasing film capable of transferring the layer onto a surface to be treated of glass and the like. Examples thereof may include flexible films composed of films of synthetic resins such as polyethylene terephthalate, polyethylene, polypropylene, polycarbonate and polyvinyl chloride with a film thickness of 15 to 125 μm. It is preferable that a mould releasing treatment is given to the above support film if necessary to easily transfer.

When the photosensitive resin layer is formed on the support film, the photosensitive resin composition of the present invention is prepared and the photosensitive resin composition of the invention is applied on the support film so that the dried film thickness is 10 to 100 μm using an applicator, a bar coater, a wire bar coater, a roll coater or a curtain flow coater. In particular, the roll coater is preferable because the film thickness uniformity is excellent and the thick film may be formed efficiently.

In the photosensitive dry film of the present invention, a protective film may be further provided on the photosensitive resin layer. By being protected by the protective film, storage, transport and handling become easy. The photosensitive dry film protected by the protective film may be previously produced and stored for a predetermined period although there is an expiration date for use. Therefore, when the device having the wiring circuit is produced, the photosensitive dry film protected by the protective film may be used instantly, and a wiring circuit forming step may be made more efficient. As this protection film, polyethylene terephthalate film, polypropylene film and polyethylene film with a thickness of about 15 to 125 μm to which silicone has been coated or burned in are suitable.

Subsequently, a method of using the photosensitive dry film of the present invention will be described. First, the photosensitive resin layer is thermally pressure-bonded on the surface of the material to be processed by lapping the revealing photosensitive resin layer over the material to be processed and moving a heating roller on the support film.

When the protective film has been provided to the dry film, the protective film is peeled from the dry film, and then the photosensitive resin layer is thermally pressure-bonded on the surface of the material to be processed by lapping the revealing photosensitive resin layer over the material to be processed and moving a heating roller on the support film. The protective film peeled from the photosensitive dry film can be reused if rolled up by a sequential take-up roller and stored.

The material to be processed may include an electrolytic copper foil substrate, an electroless copper plating substrate, a spatter copper foil substrate and a glass substrate. When the material to be processed is the electrolytic copper foil substrate, the thermal pressure-bonding may be performed in the range of a roll pressure at 1 to 5 kg/cm² and a moving speed at 0.1 to 10. m/minutes by heating a surface temperature of the electrolytic copper foil substrate to 80 to 140° C. The above electrolytic copper foil substrate may be preheated, and the temperature range at 40 to 100° C. is selected as an example of preheating temperature.

Then, a mask comprising a predetermined mask pattern is attached firmly, and subsequently, the photosensitive resin layer is selectively exposed by exposing through the mask or directly exposing a depiction.

For this exposure, the h-ray, excimer laser, X-ray and electron beam may be used. Ultraviolet light may also be irradiated using a low pressure mercury lamp, a high pressure mercury lamp, an ultra high pressure mercury lamp, an arc lamp and a xenon lamp.

An h-ray exposure apparatus is not particularly limited, and for example, the h-ray exposure apparatuses supplied from Ball semiconductor Inc., Pentax Corporation and Hitachi Via Mechanics Ltd. may be used. The photosensitive dry film according to the present invention is used suitably for LDI exposure apparatus in the h-ray exposure apparatuses.

When the photosensitive dry film according to the present invention is used, the adhesion to the material to be processed is excellent, the sensitivity is high and working property is also excellent. A pattern where the photosensitive resin layer in the exposed area stays behind is formed by removing the mask and the support film after this exposure, and developing to selectively remove the photosensitive resin layer in the unexposed area.

Examples of a developing solution used for the development may include alkali developing solutions, i.e., aqueous solutions composed of hydroxide, carbonate, bicarbonate, phosphate and pyrophosphate salts of alkali metals such as lithium, sodium and potassium; primary amine such as benzylamine and butylamine; secondary amine such as dimethylamine, dibenzylamine and diethanolamine; tertiary amine such as trimethylamine, triethylamine and triethanolamine; cyclic amine such as morpholine, piperazine and pyridine; polyamine such as ethylenediamine and hexamethylenediamine; ammonium hydroxides such as tetraethyl ammonium hydroxide, trimethylbenzyl ammonium hydroxide and trimethylphenylbenzyl ammonium hydroxide; aqueous solution including sulfonium hydroxides such as trimethyl sulfonium hydroxide, diethylmethyl sulfonium hydroxide and dimethylbenzyl sulfonium hydroxide; and additionally, alkali developing solutions commonly used such as buffers containing choline and silicate, and organic solvents commonly used, i.e., ketones such as acetone, methyl ethyl ketone, cyclohexane, methyl isoamyl ketone and 2-heptanone; polyhydric alcohols and derivatives thereof such as ethylene glycol, propylene glycol, diethylene glycol, ethylene glycol monoacetate, propylene glycol monoacetate, diethylene glycol monoacetate, or monomethyl ether thereof, monoethyl ether thereof, monopropyl ether thereof, monobutyl ether thereof or monophenyl ether thereof; and esters such as ethyl lactate, methyl acetate, ethyl acetate, butyl acetate, methyl pyruvate, ethyl pyruvate, methyl methoxypropionate and ethyl ethoxypropionate.

Since the photosensitive dry film of the present invention is excellent in development property, a favorable residual photosensitive resin layer (photoresist pattern) may be obtained even for a fine pattern.

Then, a metal wiring pattern is formed by etching the substrate or plating a resist pattern-unformed area using the patternized residual photosensitive resin layer (photoresist pattern) as the mask.

Thereafter, the photoresist pattern is peeled/removed by the aqueous solution with about pH 12 to 14 of sodium hydroxide, potassium hydroxide or organic amines.

### EXAMPLES

The present invention will be described in more detail with reference to the following Examples, but the Examples are only exemplifications for suitably illustrating the present invention, and do not limit the invention.

### Example 1

A photosensitive resin composition was prepared by stirring and mixing compounds of the following composition.

| | |
|---|---|
| (A) Alkali-soluble resin | |
| “Cyclomer P ACA200M” (trade name, supplied from Daicel Chemical Industries, | 100 parts by weight |
| molecular weight: about 15,000, Tg: 137° C.) | (in terms of solid content) |
| (B) Ethylenically unsaturated compound | |
| (B1) | |
| 2,2-Bis[4-(methacryloxy polyethoxy)phenyl]propane “BPE1300” (trade name, | 30 parts by weight |
| supplied from Shin-Nakamura Chemical Co., Ltd., molecular weight: 1684, a compound | |
| represented by the following general formula (1) wherein m + n = 30) | |
| 2,2-Bis[4-(methacryloxy polyethoxy)phenyl]propane “BPE500” (trade name, | 30 parts by weight |
| supplied from Shin-Nakamura Chemical Co., Ltd., molecular weight: 804, a compound | |
| represented by the following general formula (1) wherein m + n = 10) | |

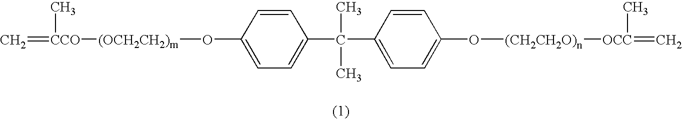

| | |
|---|---|
| Trimethylolpropane triacrylate “M-309” (trade name, supplied from Toagosei Co., | 20 parts by weight |
| Ltd.) | |
| Polyethylene glycol dimethacrylate “NK ester 4G” (trade name, supplied from | 10 parts by weight |
| Shin-Nakamura Chemical Co., Ltd.) | |
| (C) Photopolymerization initiator | |
| (C1) | |
| 4,4-Bis(diethylamino)benzophenone “EAB-F” (trade name, supplied from | 0.30 parts by weight |
| Hodogaya Chemical Co., Ltd.) | |
| (C2) | |
| 2.2-Bis(2-chlorophenyl)-4.5.4.5-tetraphenyl-1.2-biimidazole “B-CIM” (trade | 4.00 parts by weight |
| name, supplied from Hodogaya Chemical Co., Ltd.) | |
| (D) Other components | |
| Color coupler/initiator | |
| Tris(4-dimethylaminophenyl)methane “A-DMA” (trade name, supplied from | 0.30 parts by weight |
| Hodogaya Chemical Co., Ltd.) | |

A solution of the photosensitive resin composition was uniformly applied on a PET film (thickness of 16 μm) “FB60” (trade name, supplied from Toray Industries, Inc.), dried in a batch type hot air dryer at 80° C. for about 10 minutes, and subsequently a protective film “GF816” (trade name, supplied from Tamapoly Co., Ltd.) was laminated thereon to obtain a photosensitive dry film. The thickness of the photosensitive resin layer after drying was 30 μm.

A copper-clad lamination with a copper thickness of 18 μm and a plate thickness of 0.5 mm was immersed in 10% by weight of SPS (sodium persulfate) for 3 minutes (25° C.), then washed with water and dried. The above photosensitive dry film was laminated on the resulting copper-clad lamination at rolling temperature of 105° C., at a roll cylinder pressure of 3 kg/cm² and at a speed of 1 m/minute with peeling the protective film.

Then, a pattern mask [line/space=1/1 (each 8, 10, 11, 12, 13, 14, 15, 18 and 20 μm)] was placed on the PET film of the lamination obtained in this way, and exposure (exposure speed: 1.3 mm/second) was given thereto by laser power of 300 mW using an h-ray exposing machine “LAB-A2T” (trade name, supplied from Ball Semiconductor Inc.). Subsequently, the development was performed to form a pattern by spraying (spray pressure: 1.2 kg/cm² ) an aqueous solution of 1% by weight sodium carbonate (30° C.) for 20 seconds.

As a result, a minimum dimension of the pattern whose resolution and adhesion were favorable was 11 μm. An aspect ratio was 2.7 or more. Furthermore, when exposed by low exposure light intensity at an exposure speed of 1.8 mm/second, the minimum dimension of the pattern was 13 μm, and the aspect ratio was 2.3.

### Example 2

A photosensitive dry film was obtained and a pattern was formed by the same way as in Example 1, except that 0.1 parts by weight of 2-methyl-4,6-bis(trichloromethyl)-s-triazine “Triazine methyl” (supplied from Akzono Bel Co., Ltd.) was further added as the photopolymerization initiator (C).

As a result, the minimum dimension of the pattern whose resolution and adhesion were favorable was 11 μm. The aspect ratio was 2.7 or more. Furthermore, when exposed by low exposure light intensity at an exposure speed of 1.8 mm/second, the minimum dimension of the pattern was 11 μm, and the aspect ratio was 2.7 or more.

### Comparable Example 1

A photosensitive dry film was obtained and laminated on the copper-clad lamination by the same way as in Example 1, except that methacrylic acid methyl/methacrylic acid/styrene copolymer (weight ratio of 45/30/25, weight-average molecular weight: 70,000, 40% in a methyl ethyl ketone solution) was used at 100 parts by weight in terms of solid content as the alkali-soluble resin (A).

Then, a pattern mask [line/space=1/1 (each 8, 10, 11, 12, 13, 14, 15, 18 and 20 em)] was placed on the PET film of the lamination obtained in this way, and exposure (exposure speed: 0.5 mm/second) was given thereto by laser power of 300 mW using an h-ray exposing machine “LAB-A2T” (trade name, supplied from Ball Semiconductor Inc.). Subsequently, the development was performed to form the pattern by the same way as in Example 1.

As a result, the minimum dimension of the pattern whose resolution and adhesion were favorable was 20 μm, and the aspect ratio was 1.5. The fine pattern could not be formed.

### INDUSTRIAL APPLICABILITY

As in the above, the photosensitive resin composition and the photosensitive dry film of the present invention have the high sensitivity for the h-ray and are excellent in resolution of the resist pattern, and therefore are useful for forming the wiring circuit using the h-ray exposure light.

1. A photosensitive resin composition comprising:
an alkali-soluble resin (A);
an ethylenically unsaturated compound (B); and
a photopolymerization initiator (C),
wherein said alkali-soluble resin (A) has an alicyclic epoxy group-containing unsaturated compound in a part of a carboxyl group of a carboxyl group-containing acryl copolymer as well as has a weight-average molecular weight of 1,000 to 100,000, and
wherein said photopolymerization initiator (C) includes at least a photopolymerization initiator (C1) whose absorption coefficient for light with a wavelength of 405 nm is 1 or more as an essential component.

2. The photosensitive resin composition according to claim 1, wherein a glass transition temperature (Tg) of said alkali-soluble resin (A) is 100° C. or more.

3. The photosensitive resin composition according to claim 1, wherein said photopolymerization initiator (C) further includes at least one other photopolymerization initiator (C2) whose absorption property for the light with a wavelength of 405 nm is lower than that of said photopolymerization initiator (C1).

4. The photosensitive resin composition according to claim 1, wherein said photopolymerization initiator (C1) is 4,4′-bis(diethylamino)benzophenone.

5. The photosensitive resin composition according to claim 1, wherein said photopolymerization initiator (C2) is a triazine compound, a hexaarylbiimidazole compound or a mixture thereof.

6. The photosensitive resin composition according to claim 1, wherein said ethylenically unsaturated compound (B) is at least one selected from the group consisting of polyalkylene glycol di(meth)acrylate and 2,2-bis[4-((meth)acryloxy polyethoxy)phenyl]propane whose molecular weights are in the range of 500 to 2,000.

7. A photosensitive dry film having at least a photosensitive resin layer formed from the photosensitive resin composition according to claim 1 on a support film.
